(19) United States
(12) Patent Application Publication
(10) Pub. No.: US 2024/0028781 A1
(43) Pub. Date: Jan. 25, 2024

(54) IMAGING CONDITION ADJUSTING DEVICE AND IMAGING CONDITION ADJUSTING METHOD

(71) Applicant: FANUC CORPORATION, Minamitsuru-gun, Yamanashi (JP)

(72) Inventor: Junichirou YOSHIDA, Yamanashi (JP)

(21) Appl. No.: 18/025,042

(22) PCT Filed: Sep. 21, 2021
(86) PCT No.: PCT/JP2021/034570

§ 371 Date: Mar. 7, 2023

(30) Foreign Application Priority Data
Sep. 28, 2020 (JP) 2020-162038

(51) Int. Cl. G06F 30/00; G06V 10/74

(52) U.S. Cl. CPC G06F 30/00; G06V 10/761

(57) ABSTRACT

Provided is an imaging condition adjusting device for adjusting an imaging condition for capturing a distance image of an object, the imaging condition adjusting device comprising: an acquiring unit for acquiring from a 3-dimensional camera a distance image including the object disposed in the field of view of the 3-dimensional camera; a reading unit for reading a CAD model of the object; a calculating and processing unit for performing matching between distance images captured by the 3-dimensional camera under a plurality of generated imaging conditions and the CAD model, and for calculating a match between the captured distance images and the CAD model; and an imaging condition optimization unit for setting in the 3-dimensional camera an imaging condition such that the match calculated by the calculating and processing unit becomes greater than or equal to a predetermined value set in advance.

### TECHNICAL FIELD

The present invention relates to an imaging condition adjusting device and an imaging condition adjusting method.

### BACKGROUND ART

Technology for detecting a 3-dimensional position of an object such as a workpiece using a 3-dimensional camera and performing work such as picking using a robot is known. For example, see Patent Document 1.

Patent Document 1: Japanese Unexamined Patent Application, Publication No. 2019-56966

### DISCLOSURE OF THE INVENTION

### Problems to be Solved by the Invention

In order to be able to capture an image that is most suitable for detecting the 3-dimensional position of an object, the imaging conditions for imaging the object by a 3-dimensional camera are set in advance by a worker.

Imaging conditions include exposure time, amount of light from a light source, block matching size, threshold value for a block matching score, etc., and achieving an optimum setting requires a high level of skill of the worker. Therefore, setting the imaging conditions is a big burden for the worker.

There is thus a demand for automatically determining an optimum imaging condition irrespective of worker skills.

### Means for Solving the Problems

An aspect of an imaging condition adjusting device according to the present disclosure is an imaging condition adjusting device for adjusting an imaging condition for capturing a distance image of a workpiece, the imaging condition adjusting device including an acquisition unit configured to acquiring from a 3-dimensional camera a distance image including the workpiece disposed in a field of view of the 3-dimensional camera, a reading unit configured to read a CAD model of the workpiece, a calculation processing unit configured to perform matching between distance images captured by the 3-dimensional camera under a plurality of generated imaging conditions and the CAD model, and calculate degrees of match between the captured distance images and the CAD model, and an imaging condition optimization unit configured to set in the 3-dimensional camera an imaging condition under which that the degree of match calculated by the calculation processing unit becomes equal to or greater than a predetermined value set in advance.

An aspect of an imaging condition adjusting method according to the present disclosure is an imaging condition adjusting method for adjusting an imaging condition for capturing a distance image of a workpiece, the method being realized by a computer and including an acquisition step of acquiring from a 3-dimensional camera a distance image including the workpiece disposed in a field of view of the 3-dimensional camera, a reading step of reading a CAD model of the workpiece, a calculation processing step of performing matching between distance images captured by the 3-dimensional camera under a plurality of generated imaging conditions and the CAD model, and calculating degrees of match between the captured distance images and the CAD model, and an imaging condition optimization step of setting in the 3-dimensional camera an imaging condition under which the calculated degree of match becomes equal to or greater than a predetermined value set in advance.

### Effects of the Invention

According to an aspect of the present invention, an optimum imaging condition can be automatically determined irrespective of worker skills.

### BRIEF DESCRIPTION OF THE DRAWINGS

FIG. 1 illustrates an example of a configuration of a robot system according to an embodiment of the present invention;

FIG. 2 illustrates an example of a 3-dimensional camera;

FIG. 3 illustrates an example describing a distance image generation process by an image processing unit;

FIG. 4 illustrates an example describing a distance image generation process by an image processing unit;

FIG. 5 is a functional block diagram illustrating a functional configuration example of an information processing device as an imaging condition adjusting device according to an embodiment of the present invention;

FIG. 6 illustrates an example of a shape of a workpiece;

FIG. 7 illustrates an example of matching a distance image of a triangular portion of the shape of the workpiece in FIG. 6 with a CAD model;

FIG. 8 illustrates an example of a shape of a workpiece; and

FIG. 9 is a flowchart describing an example of an imaging condition adjusting process of the imaging condition adjusting device.

### PREFERRED MODE FOR CARRYING OUT THE INVENTION

An embodiment of the present invention is described below with reference to the drawings.

### Embodiment

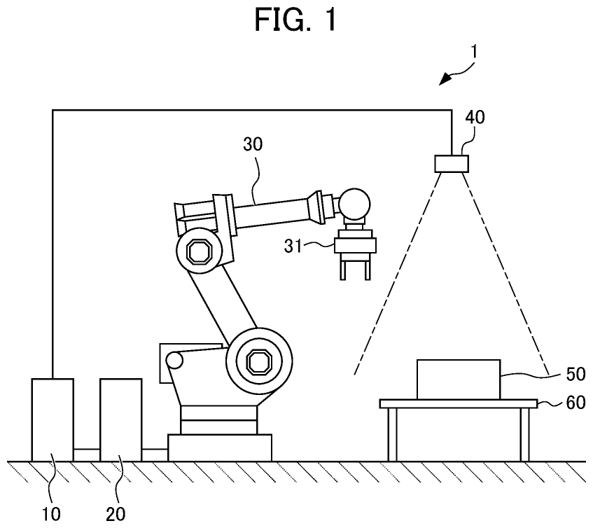

FIG. 1 illustrates an example of a configuration of a robot system 1 according to an embodiment of the present invention.

As illustrated in FIG. 1, the robot system 1 has an information processing device 10 as an imaging condition adjusting device, a robot control device 20, a robot 30, a 3-dimensional camera 40, a workpiece 50, and a workbench 60.

The information processing device 10, the robot control device 20, the robot 30, and the 3-dimensional camera 40 may be directly connected to one another via a connection interface not illustrated here. Alternatively, the information processing device 10, the robot control device 20, the robot 30, and the 3-dimensional camera 40 may be connected to one another via a network not illustrated here, such as a local area network (LAN), the Internet, or the like. In that case, the information processing device 10, the robot control device 20, the robot 30, and the 3-dimensional camera 40 are provided with a communication unit not illustrated here for communicating with one another through said connection. Further, in order to simplify description, FIG. 1 depicts the information processing device 10 and the robot control device 20 separately, and the information processing device 10 may in this case be constituted by, for example, a computer operating as an imaging condition adjusting device. The invention is not limited to such a configuration, and the information processing device 10 may be, for example, installed inside the robot control device 20 or integrated with the robot control device 20.

### <Robot Control Device 20>

The robot control device 20 is a device known to those skilled in the art for controlling an operation of the robot 30. For example, the robot control device 20 receives, from the information processing device 10, a distance image of the workpiece 50 captured by the 3-dimensional camera 40 described below under the imaging condition set by the information processing device 10 described below. The robot control device 20 identifies a position and a shape of the workpiece 50 that is the object, on the basis of the distance image received from the information processing device 10 and a known method. From the identified position and shape of the workpiece 50, the robot control device 20 generates a control signal for controlling an operation of the robot 30 so as to grip and process the workpiece 50. Then, the robot control device 20 outputs the generated control signal to the robot 30.

As described below, the robot control device 20 may include the information processing device 10.

### <Robot 30>

The robot 30 is a robot that operates on the basis of control by the robot control device 20. The robot 30 is provided with a base part for rotating about an axis in the vertical direction, an arm that moves and rotates, and an end effector 31, such as a welding gun, a gripping hand, a laser irradiation device, or the like, that is mounted to the arm.

The robot 30 drives the arm and the end effector 31 according to the control signal output by the robot control device 20 so as to grip and process the workpiece 50.

It should be noted that the specific configuration of the robot 30 is well-known to those skilled in the art, and detailed description thereof is therefore omitted.

In addition, the information processing device 10 and the robot control device 20 are calibrated in advance to associate a machine coordinate system for controlling the robot 30 and a camera coordinate system indicating the 3-dimensional position of the workpiece 50.

### <3-Dimensional Camera 40>

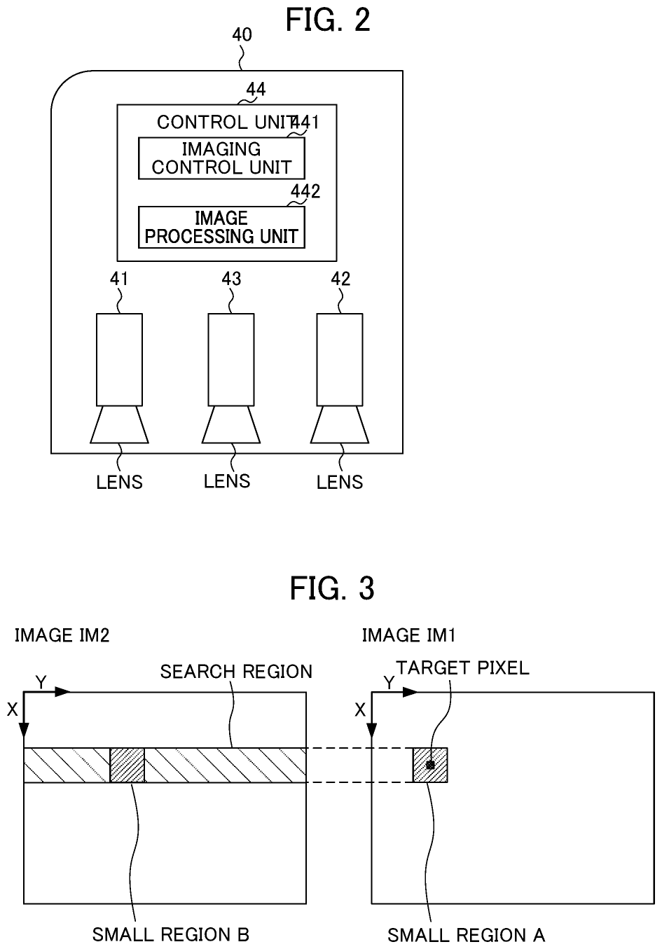

FIG. 2 illustrates an example of the 3-dimensional camera 40.

As illustrated in FIG. 2, the 3-dimensional camera 40 has two internal cameras 41, 42, a projector 43, and a control unit 44. The control unit 44 has an imaging control unit 441 and an image processing unit 442. Each of the internal cameras 41, 42 and the projector 43 has a lens.

On the basis of a control instruction from the imaging control unit 441 described below, the internal cameras 41, 42 capture 2-dimensional images wherein a pattern projected onto the workpiece 50 as the object by the projector 43 is projected onto a plane that is perpendicular to the respective optical axes of the internal cameras 41, 42. The internal cameras 41, 42 output the captured 2-dimensional images to the imaging control unit 441.

On the basis of a control instruction from the imaging control unit 441 described below, the projector 43 irradiates a predetermined pattern light at a preset amount of light onto the workpiece 50 that is the object.

The 3-dimensional camera 40 may be a stereo camera or the like, as described below.

The 3-dimensional camera 40 may be secured to a frame or the like, or installed on the arm of the robot 30.

### <Control Unit 44>

The control unit 44 is a unit that is known to those skilled in the art, having, inter alia, a central processing unit (CPU), a read-only memory (ROM), a random-access memory (RAM), a complementary metal-oxide-semiconductor (CMOS) memory, or the like, wherein these components are able to communicate with one another via a bus.

The CPU is a processor that controls the entire 3-dimensional camera 40. The CPU reads a system program and an application program stored in the ROM via the bus, and controls the entire 3-dimensional camera 40 according to the system program and the application program, whereby, as illustrated in FIG. 2, the control unit 44 is configured so as to realize the functions of the imaging control unit 441 and the image processing unit 442. The RAM stores various data such as temporary calculation data, the 2-dimensional images captured by the internal cameras 41, 42, and the imaging condition set by the information processing device 10 as described below. The CMOS memory is backed up by a battery not illustrated here, and is configured as a non-volatile memory that retains the storage state even when the power supply of the 3-dimensional camera 40 is turned off.

The imaging control unit 441 controls an imaging operation of the internal cameras 41, 42 on the basis of, for example, the imaging condition set by the information processing device 10 described below. In addition, the imaging control unit 441 controls an amount of light of the projector 43 on the basis of the imaging condition set by the information processing device 10.

The image processing unit 442 measures the distance to the workpiece 50 that is the object and generates a distance image, by performing stereoscopic analysis using, for example, two 2-dimensional images obtained from the respective internal cameras 41, 42.

Specifically, the image processing unit 442 generates the distance image from the two 2-dimensional images captured by the respective internal cameras 41, 42, using a distance measuring algorithm that is known to those skilled in the art (for example, block matching or the like).

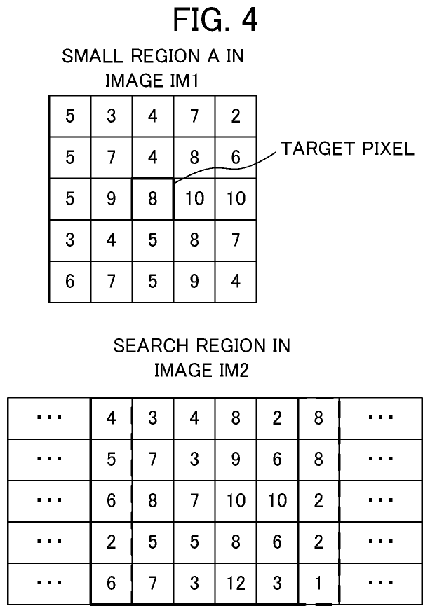

FIGS. 3 and 4 illustrate an example describing the distance image generation process by the image processing unit 442.

As illustrated in FIG. 3, from the 2-dimensional image of the workpiece 50 captured by the internal camera 41 (hereafter referred to as “image IM1”), the image processing unit 442 extracts, for example, an image range of 5 pixels by 5 pixels around a target pixel that is subject to distance measurement (this image range is also referred to as “small region A”). From the 2-dimensional image of the workpiece 50 captured by the internal camera 42 (hereafter referred to as “image IM2”), the image processing unit 442 searches, in a search region in the image IM2, for a region displaying the same pattern as the small region A of the image IM1.

The search region is a region that is, for example, 5 pixels wide, centered on the same X-coordinate as the target pixel in the image IM1. The size (5 pixels by 5 pixels) of the small region A of the image IM1 is the block matching size.

The image processing unit 442 calculates the absolute values of the differences between the contrast values (pixel values) of the pixels of the small region A in the image IM1 and the contrast values (pixel values) of the pixels in a 5 pixels by 5 pixels range in the search region in the image IM2, while shifting the search region by one pixel at a time in the Y-axis direction, as a score (Sum of Absolute Difference (SAD)) for block matching.

For example, in a case where the 5 pixels by 5 pixels of the small region A in the image IM1 have the contrast values (pixel values) indicated in the upper part of FIG. 4, and the pixels of the search region in the corresponding image IM2 have the contrast values (pixel values) indicated in the lower part of FIG. 4, the image processing unit 442 calculates the block matching score for the region of the search region indicated by a solid thick line in the image IM2 and the small region A in the image IM1 as follows: |5-4|+|3-3|+|4-4|+|7-8|+|2-2| . . . +|4−3|=16. In addition, the image processing unit 442 calculates the block matching score for the region indicated by a thick dashed line and the small region A in the image IM1 as follows: |5-3|+|3-4|+|4-8|+|7-2|+|2-8| . . . +|4-1|=34. The contrast values (pixel values) are, for example, values in a range of 0 to 255.

The image processing unit 442 may be configured to determine that the region having the lowest block matching score (degree of match) calculated for the search region in the image IM2, for example, the region indicated by the solid line, which is the small region B in FIG. 3, as the region with the highest degree of match with respect to the small region A in the image IM1.

Here, as illustrated in FIG. 2, the internal cameras 41, 42 capture images of the workpiece 50 from different positions, and therefore, as illustrated in FIG. 3, the positions of the patterns in the images IM1, IM2, that is to say the position of the small region A in the image IM1 and the position of the small region B in the image IM2, differ from each other. For example, in a case where the position (X, Y) of the target pixel of the small region A in the image IM1 is (200, 150), and the position (X, Y) of the center pixel of the small region B in the image IM2 is (200, 300), the difference between the position of the small region A in the image IM1 and the position of the small region B in the image IM2 (hereafter referred to as “parallax”) is 150 (300-150).

On the basis of the calculated parallax, the image processing unit 442 is able to calculate the distance between the position on the workpiece 50 corresponding to the position of the target pixel of the small region A in the image IM1 and the 3-dimensional camera 40. Thus, by performing block matching with respect to the entire image IM1 while changing the position of the target pixel in the image IM1, the image processing unit 442 is able to generate a 3-dimensional point group in the field of vision of the 3-dimensional camera 40 as a distance image. The image processing unit 442 outputs the generated distance image to the information processing device 10 described below.

It should be noted that the image processing unit 442 may output the 2-dimensional images captured by the internal cameras 41, 42 together with the distance image to the information processing device 10.

The workpiece 50 is placed, for example, on the workbench 60. The workpiece 50 may be any object that can be gripped or processed by the end effector 31 mounted to the arm of the robot 30, and the shape, etc. thereof is not particularly limited.

### <Information Processing Device 10>

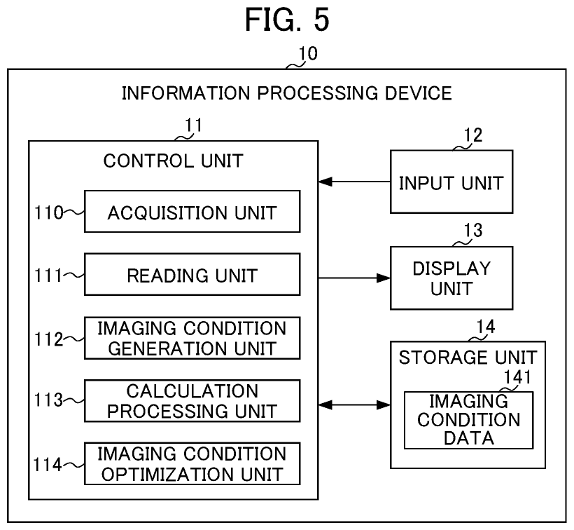

FIG. 5 is a functional block diagram illustrating a functional configuration example of the information processing device 10 as the imaging condition adjusting device according to an embodiment of the present invention.

The information processing device 10 is a computer that is known to those skilled in the art, and operates as an image condition adjusting device. As illustrated in FIG. 5, the information processing device 10 has a control unit 11, an input unit 12, a display unit 13, and a storage unit 14. The control unit 11 has an acquisition unit 110, a reading unit 111, an imaging condition generation unit 112, a calculation processing unit 113, and an imaging condition optimization unit 114.

### <Input Unit 12>

The input unit 12 is, for example, a keyboard or a touch panel disposed at the display unit 13 described below, and receives an input from a worker. Specifically, the worker inputs, for example, via the input unit 12, an instruction or the like for adjusting the imaging condition of the 3-dimensional camera 40.

### <Display Unit 13>

The display unit 13 is, for example, a liquid crystal display or the like, and displays the distance image of the 3-dimensional camera 40 acquired by the acquisition unit 110, and a CAD model indicating the shape of the workpiece 50 read by the reading unit 111 described below, etc.

### <Storage Unit 14>

The storage unit 14 is a ROM or a hard disk drive (HDD) or the like, and may store various control programs and imaging condition data 141.

The imaging condition data 141 is imaging conditions that may be applied to the internal cameras 41, 42 of the 3-dimensional camera 40, and may contain a plurality of imaging conditions that are generated in advance by the imaging condition generation unit 112 described below. Each of the plurality of imaging conditions contained in the imaging condition data 141 includes at least one of an exposure time, an amount of light from the projector 43 that is the light source, a block matching size, a threshold value for a block matching score, etc.

Regarding the exposure time, a shorter exposure time of the internal cameras 41, 42 makes it easier to recognize bright objects, and a longer exposure time makes it easier to recognize dark objects.

Regarding the amount of light of the projector 43, a greater amount of light reduces susceptibility to the influence of ambient light, but makes it more likely that halation occurs, whereby portions struck by strong light become blurred white.

By setting the block matching score to a low value, a distance image composed of 3-dimensional points of a small region with a high degree of match can be obtained. However, if the block matching score is set too low, the number of small regions that meet the degree of match decreases, and it is therefore possible that there are not enough 3-dimensional points.

By setting the size of the small region to be small, such as 5 pixels by 5 pixels, it becomes easier to capture minute changes in shape of the workpiece 50 that is the object, but noise-like 3-dimensional points may occur in the distance image.

### <Control Unit 11>

The control unit 11 is a unit that is known to those skilled in the art, having, inter alia, a CPU, a ROM, a RAM, and a CMOS memory, wherein these components are able to communicate with one another via a bus.

The CPU is a processor that controls the entire information processing device 10. The CPU reads a system program and an application program stored in the ROM via the bus, and controls the entire information processing device 10 according to the system program and the application program. Thus, as illustrated in FIG. 5, the control unit 11 is configured so as to realize the functions of the acquisition unit 110, the reading unit 111, the imaging condition generation unit 112, the calculation processing unit 113, and the imaging condition optimization unit 114.

The acquisition unit 110 acquires, from the 3-dimensional camera 40, a distance image including the workpiece 50 as the object disposed in the field of vision of the 3-dimensional camera 40.

The reading unit 111 reads data of a CAD model indicating the shape of the workpiece 50 from an external device (not illustrated) such as a CAD/CAM device or the like.

The imaging condition generation unit 112 generates a plurality of imaging conditions and stores the plurality of generated imaging conditions in the imaging condition data 141.

Specifically, the imaging condition generation unit 112 may, for example, generate the plurality of imaging conditions, using a standard imaging condition as a base, by changing at least one parameter such as the exposure time, the amount of light of the projector 43, the block matching size, or the threshold value of the block matching score within a range of preset numerical values. The imaging condition generation unit 112 may store the plurality of generated imaging conditions in the imaging condition data 141.

The calculation processing unit 113, for example, on the basis of the plurality of imaging conditions stored in the imaging condition data 141, performs matching between the distance images captured by the 3-dimensional camera 40 and the CAD model, and calculates degrees of match between the captured distance images and the CAD model.

Specifically, the calculation processing unit 113, for example, selects a standard imaging condition from the plurality of imaging conditions, and first acquires, via the acquisition unit 110, a distance image captured (generated) by the 3-dimensional camera 40 on the basis of the selected imaging condition. The calculation processing unit 113 performs matching between the acquired distance image and the CAD model read by the reading unit 111, and determines whether or not the 3-dimensional points of the distance image and the corresponding positions of the CAD model are separated by a distance equal to or greater than a prescribed value (e.g., 1 mm) that is set in advance. The calculation processing unit 113 calculates the degree of match between the distance image and the CAD model as a CAD model matching score, by accumulating the 3-dimensional points that are separated by a distance equal to or greater than the prescribed value as error points and the lengths of the separating distances.

Next, the calculation processing unit 113 may select an imaging condition wherein a parameter has been changed so as to, for example, reduce the block matching size, and acquire a distance image captured (generated) by the 3-dimensional camera 40 on the basis of the selected imaging condition. The calculation processing unit 113 performs matching between the acquired distance image and the CAD model and calculates the degree of match (CAD model matching score). The calculation processing unit 113 may select the next imaging condition on the basis of a determination by the imaging condition optimization unit 114 described below as to whether or not the degree of match under the current imaging condition is higher than the degree of match under the previous imaging condition. For example, when the degree of match under the current imaging condition is higher than the degree of match under the previous imaging condition, the imaging condition has improved, and thus the calculation processing unit 113 may select an imaging condition where the parameter is changed in the same way, such as having the block matching size be further reduced, and acquire a distance image captured (generated) by the 3-dimensional camera 40 on the basis of the selected imaging condition. Then, the calculation processing unit 113 may perform matching between the acquired distance image and the CAD model and calculate the degree of match (CAD model matching score).

On the other hand, when the degree of match under the current imaging condition is lower than the degree of match under the previous imaging condition, the imaging condition has worsened, and thus the calculation processing unit 113 may select an imaging condition where the parameter is changed in a different way, such as having the block matching size be increased, and acquire a distance image captured (generated) by the 3-dimensional camera 40 on the basis of the selected imaging condition. Then, the calculation processing unit 113 may perform matching between the acquired distance image and the CAD model and calculate the degree of match (CAD model matching score).

Thus, the information processing device 10 is capable of finding the optimum imaging condition.

Here, the degree of match (CAD model matching score) calculated by the calculation processing unit 113 changes according to the shape of the workpiece 50, even when the imaging condition is the same.

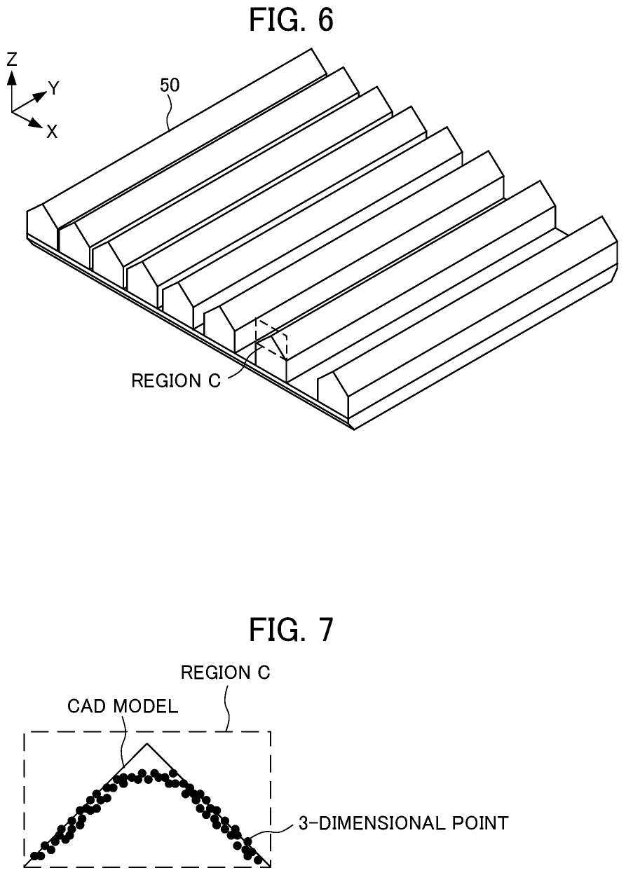

FIG. 6 illustrates an example of the shape of the workpiece 50. FIG. 7 illustrates an example of matching a distance image of a triangular portion of the shape of the workpiece 50 in FIG. 6 with the CAD model.

In the ridge portion such as the triangular portion of the small region C in the ZX plane indicated by a dashed line in the shape of the workpiece 50 illustrated in FIG. 6, that is to say, in the portion that undergoes a significant change in shape, the degree of match with the CAD model becomes low, because the CAD model indicated by the solid line and the 3-dimensional points indicated by the black dots in FIG. 7 are separated by a distance that is equal to or greater than the prescribed value.

In this case, in order to capture the detailed features of the triangular portion, etc. of the workpiece 50 illustrated in FIG. 6 with high sensitivity, an imaging condition wherein the block matching size is set to be small may be selected, and the 3-dimensional camera 40 may be caused to capture an image of the workpiece 50 on the basis of the selected imaging condition. Thus, the 3-dimensional camera 40 is able to capture (generate) a distance image that captures the detailed features of the triangular portion, etc. of the workpiece 50 illustrated in FIG. 6 with high sensitivity, and the calculation processing unit 113 is able to calculate a higher degree of match.

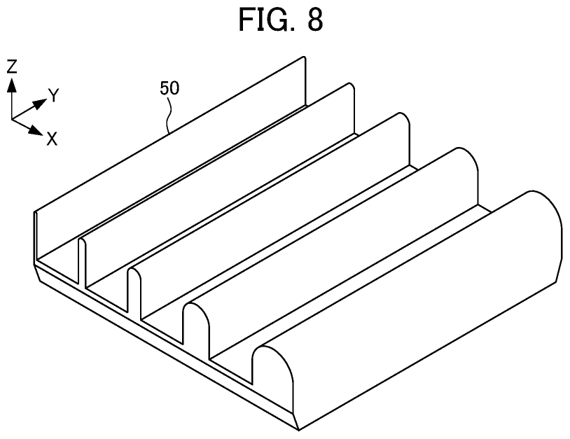

In addition, when the workpiece 50 has a shape including curved surface portions or the like, as illustrated in FIG. 8, it is difficult for the 3-dimensional camera 40 to capture a precise distance image of the curved surface portions, and therefore, an imaging condition wherein the block matching score is set to be strict may be selected. Thus, in the distance image captured (generated) by the 3-dimensional camera 40, information regarding the curved surface portions is deliberately reduced, whereby other planar portions become dominant, allowing for a higher degree of match with the CAD model.

The imaging condition may, for example, be selected from among the plurality of imaging conditions stored in the imaging condition data 141 by an input by a worker via the input unit 12.

The imaging condition optimization unit 114 sets in the 3-dimensional camera 40 an imaging condition under which the degree of match calculated by the calculation processing unit 113 becomes equal to or greater than a predetermined value set in advance.

Specifically, when the degrees of match for the imaging conditions are calculated in sequency by the calculation processing unit 113, the imaging condition optimization unit 114 may set the imaging condition at the point in time when the calculated degree of match becomes equal to or greater than the set predetermined value in the 3-dimensional camera 40 as an optimum imaging condition.

The predetermined value is preferably set as appropriate according to the required precision, etc. of the distance image.

### <Imaging Condition Adjusting Process of the Information Processing Device 10>

Next, an example of the operations involved in the imaging condition adjusting process of the information processing device 10 is described.

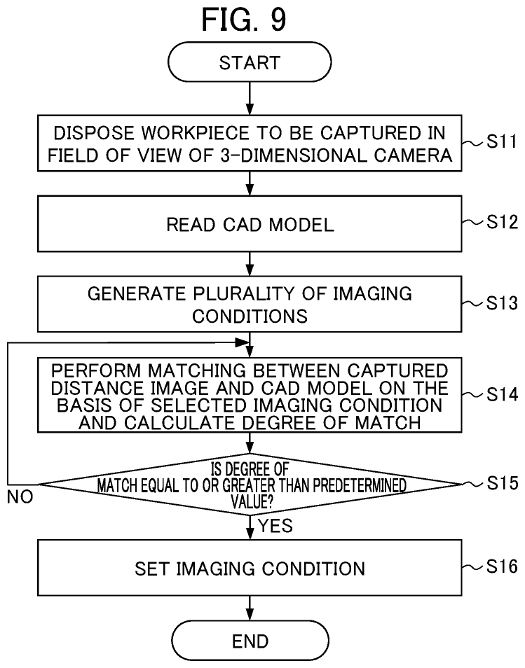

FIG. 9 is a flowchart describing an example of an imaging condition adjusting process of the information processing device 10.

At Step S11, the information processing device 10 causes the robot control device 20 to operate the robot 30, whereby the workpiece 50 that is the object is disposed on the workbench 60 in the field of view of the 3-dimensional camera 40.

At Step S12, the reading unit 111 reads a CAD model indicating the shape of the workpiece 50 from an external device (not illustrated) such as a CAD/CAM device or the like.

At Step S13, the imaging condition generation unit 112 generates a plurality of imaging conditions, and stores the plurality of generated imaging conditions in the imaging condition data 141.

At Step S14, the calculation processing unit 113, on the basis of an imaging condition selected from the plurality of imaging conditions stored in the imaging condition data 141, performs matching between a distance image captured (generated) by the 3-dimensional camera 40 and the CAD model read at Step S12, and calculates a degree of match (CAD model matching score) between the distance image and the CAD model.

At Step S15, the imaging condition optimization unit 114 determines whether or not the degree of match calculated at Step S14 is equal to or greater than the predetermined value. When the degree of match is equal to or greater than the predetermined value, the process proceeds to Step S16. However, when the degree of match is less than the predetermined value, the process returns to Step S14 in order to calculate the degree of match (CAD model matching score) under the next imaging condition.

At Step S16, the imaging condition optimization unit 114 sets the imaging condition under which the degree of match is equal to or greater than the predetermined value in the 3-dimensional camera 40.

In this way, the information processing device 10 according to an embodiment of the present invention performs matching between the distance image generated by the 3-dimensional camera 40 under an imaging condition selected from a plurality of generated imaging conditions and the read CAD model, and calculates the degree of match (CAD model matching score) between the distance image and the CAD model. At a point in time when the calculated degree of match becomes equal to or greater than the predetermined value, the information processing device 10 sets the imaging condition at that point in time in the 3-dimensional camera 40.

Thus, the information processing device 10 is capable of automatically determining an optimum imaging condition irrespective of worker skills, and reducing the burden for the worker of setting the imaging condition.

An embodiment has been described above, but the information processing device 10 is not limited to this embodiment, and may be altered and modified within the scope of achieving the purpose of the invention.

### <Variant 1>

In the embodiment described above, the information processing device 10 is a different device from the robot control device 20, but the invention is not so limited. For example, the information processing device 10 may be included in the robot control device 20.

### <Variant 2>

Further, in the embodiment described above, the imaging condition optimization unit 114 sets the imaging condition at the point in time when the degree of match becomes equal to or greater than the predetermined value in the 3-dimensional camera 40, but the invention is not so limited. For example, the calculation processing unit 113 may calculate degrees of match between the distance image and the CAD model for all of the plurality of imaging conditions generated by the imaging condition generation unit 112 and stored in the imaging condition data 141. Then, the imaging condition optimization unit 114 may determine the imaging condition that has the highest degree of match out of all the degrees of calculated match.

Thus, the information processing device 10 is capable of setting a more optimum imaging condition in the 3-dimensional camera 40.

### <Variant 3>

Still further, in the embodiment described above, a plurality of imaging conditions are created, and images are captured on the basis of an image condition selected therefrom as needed, but the invention is not so limited. For example, the next imaging condition may be generated on the basis of a comparison of the degree of match under the current imaging condition and the degree of match under the previous imaging condition. Specifically, when the degree of match has improved, the imaging condition may be modified in the same way as the previous one, and when the degree of match has deteriorated, the imaging condition may be modified in the opposite way from the previous one.

### <Variant 4>

Still further, before the comparison of the degrees of match between the distance image and the CAD model is performed, the distance image may be processed. For example, part of the distance image may be clipped or minimized in order to speed up calculation of the degree of match. In addition, the distance image may be processed by applying a filter to blur the distance image, etc., if doing so would make the comparison with the CAD model more effective.

The functions included in the information processing device 10 according to an embodiment of the present invention may each be realized by hardware, software, or a combination thereof. Here, being realized by software means being realized by a computer reading and executing a program.

The program may be stored using various types of non-transitory computer-readable media and provided to the computer. Non-transitory computer-readable media include various types of tangible storage media. Examples of non-transitory computer-readable media include magnetic storage media (e.g., flexible discs, magnetic tapes, hard disk drives), magneto-optical storage media (e.g., magneto-optical discs), CD-ROM (Read Only Memory), CD-R, CD-R/W, and semiconductor memories (e.g., mask ROM, PROM (Programmable ROM), EPROM (Erasable PROM), flash ROM, and RAM). In addition, the program may be provided to the computer by various types of transitory computer-readable media. Examples of transitory computer-readable media include electric signals, optical signals, and electromagnetic waves. Transitory computer-readable media may provide the program to the computer via wired communication paths such as electric wires and optical fibers, or the like, or via wireless communication paths.

It should be noted that the steps describing the program stored in the storage medium obviously include a process executed chronologically according to the order thereof, and also includes processes executed in parallel or separately, and not necessarily in chronological order.

Rephrasing the above description, the imaging condition adjusting device and the imaging condition adjusting method according to the present disclosure may take on embodiments having the following configurations.

(1) The imaging condition adjusting device (information processing device 10) according to the present disclosure is an imaging condition adjusting device for adjusting an imaging condition for capturing a distance image of a workpiece 50, and includes an acquisition unit 110 configured to acquire from a 3-dimensional camera 40 a distance image including the workpiece 50 disposed in a field of view of the 3-dimensional camera 40, a reading unit 111 configured to read a CAD model of the workpiece 50, a calculation processing unit 113 configured to perform matching between distance images captured by the 3-dimensional camera 40 under a plurality of generated imaging conditions and the CAD model, and calculate degrees of match between the captured distance images and the CAD model, and an imaging condition optimization unit 114 configured to set in the 3-dimensional camera 40 an imaging condition under which the degree of match calculated by the calculation processing unit 113 becomes equal to or greater than a predetermined value set in advance.

According to this imaging condition adjusting device, an optimum imaging condition can be automatically determined irrespective of worker skills.

(2) In the imaging condition adjusting device according to configuration (1), the imaging condition optimization unit 114 may determine the imaging condition that has the highest degree of match out of the degrees of match of the plurality of imaging conditions calculated by the calculation processing unit 113.

Thus, the information processing device is capable of setting a more optimum imaging condition in the 3-dimensional camera 40.

(3) In the imaging condition adjusting device according to configuration (1) or (2), the imaging condition may include at least one of an exposure time, an amount of light from the projector 43, a block matching size, or a threshold value for a block matching score.

Thus, the imaging condition adjusting device is capable of acquiring a more optimum distance image.

(4) The imaging condition adjusting method according to the present disclosure is an imaging condition adjusting method for adjusting an imaging condition for capturing a distance image of a workpiece 50, the method being realized by a computer and including an acquisition step of acquiring from a 3-dimensional camera 40 a distance image including the workpiece 50 disposed in a field of view of the 3-dimensional camera 40, a reading step of reading a CAD model of the workpiece 50, a calculation processing step of performing matching between distance images captured by the 3-dimensional camera 40 under a plurality of generated imaging conditions and the CAD model, and calculating degrees of match between the captured distance images and the CAD model, and an imaging condition optimization step of setting in the 3-dimensional camera 40 an imaging condition under which the calculated degree of match becomes equal to or greater than a predetermined value set in advance.

This imaging condition adjusting method may exhibit the same effect as configuration (1).

### EXPLANATION OF REFERENCE NUMERALS

1 Robot system
10 Information processing device
11 Control unit
110 Acquisition unit
111 Reading unit
112 Imaging condition generation unit
113 Calculation processing unit
114 Imaging condition optimization unit
12 Input unit
13 Display unit
14 Storage unit
141 Imaging condition data
20 Robot control device
30 Robot
40 3-dimensional camera

1. An imaging condition adjusting device for adjusting an imaging condition for capturing a distance image of a workpiece, the imaging condition adjusting device comprising:
an acquisition unit configured to acquire from a 3-dimensional camera a distance image including the workpiece disposed in a field of view of the 3-dimensional camera;
a reading unit configured to read a CAD model of the workpiece;
a calculation processing unit configured to perform matching between distance images captured by the 3-dimensional camera under a plurality of generated imaging conditions and the CAD model, and calculate degrees of match between the captured distance images and the CAD model; and
an imaging condition optimization unit configured to set in the 3-dimensional camera an imaging condition under which the degree of match calculated by the calculation processing unit becomes equal to or greater than a predetermined value set in advance.

2. The imaging condition adjusting device according to claim 1, wherein
the imaging condition optimization unit determines the imaging condition that has the highest degree of match out of the degrees of match of the plurality of imaging conditions calculated by the calculation processing unit.

3. The imaging condition adjusting device according to claim 1, wherein
the imaging condition includes at least one of an exposure time, an amount of light from a light source, a block matching size, or a threshold value for a block matching score.

4. An imaging condition adjusting method for adjusting an imaging condition for capturing a distance image of a workpiece, the method being realized by a computer and including:
an acquisition step of acquiring from a 3-dimensional camera a distance image including the workpiece disposed in a field of view of the 3-dimensional camera;
a reading step of reading a CAD model of the workpiece;
a calculation processing step of performing matching between distance images captured by the 3-dimensional camera under a plurality of generated imaging conditions and the CAD model, and calculating degrees of match between the captured distance images and the CAD model; and
an imaging condition optimization step of setting in the 3-dimensional camera an imaging condition under which the calculated degree of match becomes equal to or greater than a predetermined value set in advance.
